(19) United States
(12) Patent Application Publication
(10) Pub. No.: US 2017/0149432 A1
(43) Pub. Date: May 25, 2017

(54) Integrated Interconnection Module Allowing Dielectric Shift Sensing Activation of a Variety of Occupancy Monitors

(71) Applicant: Paul Newham, Helotes, TX (US)

(72) Inventor: Paul Newham, Helotes, TX (US)

(21) Appl. No.: 15/276,720

(22) Filed: Sep. 26, 2016

Related U.S. Application Data
(60) Provisional application No. 62/232,053, filed on Sep. 24, 2015.

(51) Int. Cl. H03K 17/96; G01R 27/26; G08B 21/04

(52) U.S. Cl. CPC H03K 17/962; G08B 21/0461; G01R 27/2605

(57) ABSTRACT

Disclosed is an integrated interconnect cable component for allowing the operation of dielectric shift sensor elements with a variety of control monitors associated with pressure switch based patient alarm systems. The interconnect cable component may be used for connecting a dielectric shift sensing mat (associated with a patient monitoring system) with any of a variety of different pressure switch based control unit module as utilized in conjunction with patient occupancy alarm systems. The interconnect component includes an integrated driver, sensor, comparator, calibration, logic circuit; a relay activation circuit; and a power supply (battery). The cabled component takes the dielectric shift measured across the contacts for a sensor mat and drives a relay activation circuit accordingly. The relay activation circuit in turn provides the on/off switch condition that the existing pressure switch monitor circuit expects to see at the connection cable.

### CROSS REFERENCES TO RELATED APPLICATIONS

This application claims the benefit under Title 35 United States Code §119(e) of U.S. Provisional Patent Application Ser. No.: 62/232,053; Filed: Sep. 24, 2015; the full disclosure of which is incorporated herein by reference.

### BACKGROUND OF THE INVENTION

1. Field of the Invention

The present invention relates generally to patient occupancy alarm systems for detecting movement of a patient from beds or chairs. The present invention relates more specifically to an integrated interconnect cable component for allowing the operation of dielectric shift sensor elements with a variety of control monitors associated with pressure switch based patient alarm systems.

2. Description of the Related Art

Patient occupancy alarm systems (“bed/chair alarms”) typically utilize a pressure sensing sensor element (a “switch-mat”) placed between the patient's body mass and the supporting bed or chair surface. Compression of the sensing element closes two conductive elements (“the switch”) allowing a driver current from the alarm control unit module to activate a monitor condition. Release of compression deactivates the switch causing an alarm mode to activate.

It is not uncommon for a healthcare facility to initially utilize a patient occupancy alarm system that includes a pressure switch sensor in conjunction with a matched pressure switch monitor (driver control module). It is also not uncommon for such healthcare facilities to subsequently purchase replacement sensor arrays and to utilize such replacement sensors with their existing control unit modules. Most often these sensor arrays and control unit modules are each directed to pressure switch based systems, and most commonly the specific pressure switch sensors are matched to specific pressure switch control unit modules such that the “signal” (open/closed condition) output by the sensor can be appropriately read and interpreted by the control unit.

More recently, the use of dielectric shift sensing elements in patient monitoring systems has increased. A dielectric shift sensing patient occupancy monitoring system is described in detail in U.S. Pat. No. 6,025,782 issued to Newham on Feb. 15, 2000, entitled Device for Monitoring the Presence of a Person using Proximity Induced Dielectric Shift Sensing (the '782 Patent), the full disclosure of which is incorporated herein by reference. Further features of such a system are described in detail in U.S. Pat. No. 6,297,738 issued to Newham on Oct. 2, 2001, entitled Modular System for Monitoring the Presence of a Person using a Variety of Sensing Devices (the '738 Patent), the full disclosure of which is incorporated herein by reference. Further features and accessory components for such a system are also described in detail in U.S. Pat. No. 6,778,090 issued to Newham on Aug. 17, 2004, entitled Modular System for Monitoring the Presence of a Person using a Variety of Sensing Devices (the '090 Patent), the full disclosure of which is incorporated herein by reference.

An example of an effort to make dielectric shift sensing elements compatible with systems designed to use pressure switch type sensing mats is briefly described in the '738 Patent referenced above, FIG. 10 of which is recreated herein as FIG. 1 for reference. A brief description of this approach to creating an interconnection between a dielectric shift sensing mat and a pressure switch control system is provided below. This effort, however, relies on the use of the existing driver sensor circuit module associated with the dielectric shift sensing mat in conjunction with a separate interconnect module.

It would be desirable to have an interconnect cable component that did not require the use of the separate driver sensor circuit module in order to permit the use of dielectric shift sensing mats with existing pressure sensing mat control systems. It would be preferable if the dielectric shift sensors and pressure switch control modules could be connected together, even if manufactured by different companies. It would further be desirable if the interconnect cable component incorporated a self-referencing function that allowed it to automatically detect and configure for the type of pressure switch control system being used.

### BRIEF DESCRIPTION OF THE DRAWINGS

FIG. 1 is schematic block diagram showing a previous effort to provide compatibility between a dielectric shift sensing mat and a pressure switch based control system.

FIG. 2 is a schematic block diagram of the system of the present invention that integrates the necessary circuitry into a single interconnect component.

FIG. 3 is a schematic block diagram of the system of the present invention that integrates the necessary circuitry into a dual interconnect component.

### DETAILED DESCRIPTION OF THE PREFERRED EMBODIMENTS

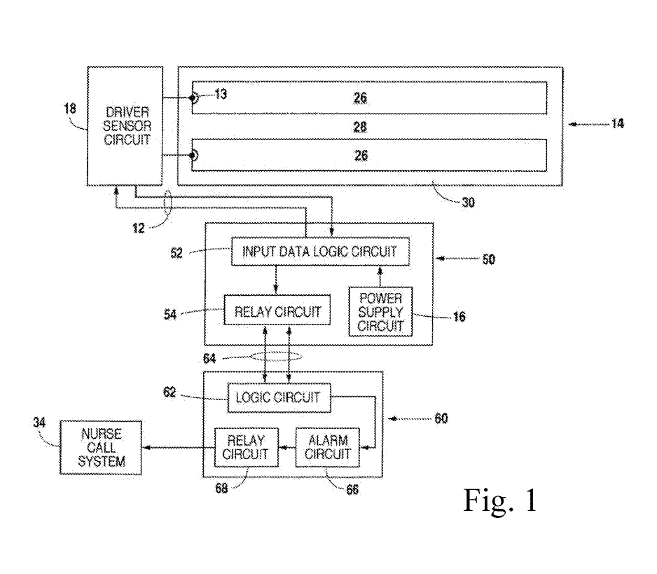

As indicated above, the structures of the present invention lend themselves particularly to be retrofit into existing patient monitor systems previously based upon alternate sensing mechanisms, including pressure switch sensing systems. In many cases, existing electronics are already in place that provides the link between the patient monitor and the nurse's call system. FIG. 1 describes just such a situation and indicates a previous approach to creating an interconnection between a dielectric shift sensing mat and a pressure switch control system that utilizes multiple circuit modules. The manner in which this previous system interconnects two disparate systems is, however, instructive as to the goals and objectives of the present invention.

In FIG. 1 interconnect adaptor module 50 connects with driver/sensor circuit 18. The structures of sensing element 14 and its capacitive array 26 with inter-space 28 positioned within substrate 30 are basically as described in the above referenced Newham Patents. Within interconnect adaptor module 50 is input data logic circuit 52 which in turn is connected with relay circuit 54. Both are provided with power from power supply circuit 16. Power supply circuit 16 also supplies power through interconnection 12 to driver sensor circuit 18.

Interconnect adaptor module 50 is connected to an existing switch-based monitor/control unit 60 through logic circuit 62 contained therein. Connection 64 therefore typically carries an on/off condition between interconnect adaptor module 50 and existing switch based monitor/control unit 60. Logic circuit 62 of switch based monitor/control unit 60 typically generates an electrical signal into connections 64 which, if the system were using a mechanical switch sensor would determine the opening or closing of contacts within that sensor. The driver current produced by logic circuit 62 might typically be 6-10 volts at 2-3 microamps. Should the contacts of a mechanical switch sensor be closed, thereby completing the driver circuit, logic circuit 62 of the switch based monitor/control unit 60 would signal and indicate a monitoring status mode within monitor/control unit 60. Should the switch sensor contacts open in such an arrangement, then by sensing an open circuit status, logic circuit 62 would in turn generate an appropriate status signal which would activate alarm circuit 66 and relay circuit 68 to effectively generate an alarm condition from monitor/control unit 60.

The principle effect of the previously described interconnect adaptor module 50 is to replace, in an electrically transparent manner, the contact points of a mechanical switch sensor with those of an appropriate relay circuit (most preferably of a solid state design) which will effectively imitate the mechanical switch sensor from the viewpoint of monitor/control unit 60. A capacitance shift value produced by sensing element 14, which might typically be 20 picofarads in a resting, unoccupied state, to 200 picofarads or more in an active occupied state is converted by driver/sensor circuit 18 to an equivalent frequency drop generated by an appropriate oscillator circuit imbedded in driver/sensor circuit 18. This oscillator driven frequency drop may typically be 100 kilocycles in a resting unoccupied state to 20 kilocycles in an active occupied state. This frequency shift signal is carried through conductive elements 12 from driver/sensor circuit 18 to input data logic circuit 52 within interconnect adaptor module 50. By analyzing this input frequency shift, the input data logic circuit 52 may determine the active/occupied status or equivalent inactive/unoccupied status of capacitive sensing element 14. This data is fed into relay circuit 54, also contained within interconnect adaptor module 50, which will open or close its secondary conducting elements interfacing directly to logic circuit 62 of monitor control unit 60. In this manner, an alternative manufacturer's monitor control unit 60 may, through interconnect adaptor module 50 and driver/sensor circuit 18 directly interface, and equivalently and appropriately respond to status signals generated by the capacitive sensing elements of the present invention.

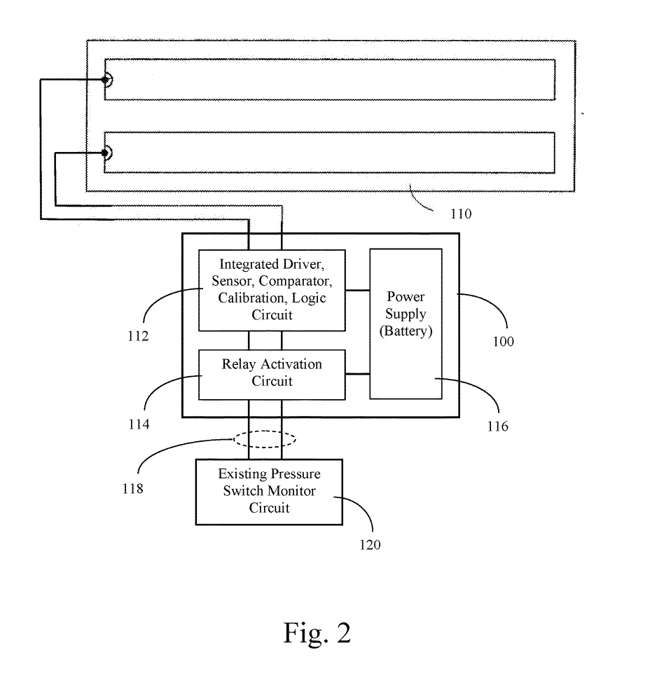

It is the objective of the present invention to simplify the approach of the previously described effort by eliminating the need for the separate driver/sensor circuit module. FIG. 2 shows the basic structure of the system of the present invention. In this view, a flexible capacitance sensor 110 (a dielectric shift sensor) is shown connected to the integrated interconnect cable component 100 of the present invention. Interconnect component 100 includes three basic elements incorporated into a single module. These include integrated driver, sensor, comparator, calibration, logic circuit 112; relay activation circuit 114; and power supply (battery) 116. Circuit 112 takes the dielectric shift measured across the contacts for sensor mat 110 and drives relay activation circuit according to the condition of the mat (patient on or patient off). Relay activation circuit in turn provides the on/off switch condition that the existing pressure switch monitor circuit 120 expects to see at the connection cable 118.

Connection cable 118 would in the preferred embodiment be a section of typical “phone wire” comprising an insulated sheath enclosing four conductive wires, conventionally provided in color-coded insulation as red (R), black (B), yellow (Y), and green (G) conductors. In many applications these conductive wires are paired, R and B (for example), Y and G (for example), and the paired wires then jointly connected to the various circuit components. However, in an attempt to defeat connection of one manufacturer's switch-mat to another manufacturer's control-unit module, multiple combinations and configurations of the basic four wire (R, B, Y, G) cable have been devised (for example, R and B/Y; Y and G/B; etc.). By allowing any combination/configuration of the basic four-wire R, B, Y, G connectors within cable to be reconfigured, any control unit module can be connected. This configuration may be hardwired into the interconnect device of the present invention and may provide for a variety of different functioning pressure switch based control systems. A plurality of different hard wired adaptor cables might be provided, each specifically designed for use in connecting to a specific brand of control unit.

In the preferred embodiment, however, the circuitry associated with relay activation circuit 114 could incorporate calibration circuitry that would initially “interrogate” the existing pressure switch monitor circuit to detect and determine the specific “signal” the system is setup to look for. The relay activation circuit may then configure itself to appropriately activate or deactivate the four wires within the cable 118 to match the circuitry of the existing control system.

Once again, the structures of the present invention lend themselves particularly to be retrofit into existing patient monitor systems previously based upon alternate sensing mechanisms, including pressure switch sensing systems. As discussed above, existing electronics are often already in place that provide the link between the patient monitor and the nurse's call system. Reference is made again to FIG. 1 which describes a previous approach to creating an interconnection between a dielectric shift sensing mat and a pressure switch control system that utilizes multiple circuit modules. The manner in which this previous system interconnects two disparate systems is, once again instructive as to the goals and objectives of the improved systems of the present invention. The principle effect of the previously described interconnect adaptor module was to replace, in an electrically transparent manner, the contact points of a mechanical switch sensor with those of an appropriate relay circuit (most preferably of a solid state design) which will effectively imitate the mechanical switch sensor from the viewpoint of the monitor/control unit.

It is an objective of the alternative embodiment of the present invention to simplify the approach of the previously described effort by eliminating the need for the separate driver/sensor circuit module. A plurality of different hard wired adaptor cables might be provided, each specifically designed for use in connecting to a specific brand of control unit. These include the following type-groups of connectors:

Cable C-030: Bed-Ex; Microtech (91780, 81840, 81781); UMP; Nurse Assist; Curbell; RN+; AliMed (IQ Duo No Serial Number TR2); Chair Check (Bed Check); and Tabs;

Cable C-030R: Bed Check; Microtech (81860, 81850); Medline; Direct Supply Attendant; Smart (19129, TL2100E); AliMed (Serial Number TR2); and Rondish;

Cable C-040: Ultimate Safety;

Cable C-050R: Code-Alert;

Cable C-060R: Smart (TL04);

Cable C-070: Personal Safety;

Cable C-110: Posey (Sitter Select & new Keepsafe);

Cable C-110R: Posey (old Keepsafe);

Cable C-120: Tabs (25022);

Cable C-130: AliMed (IQ Easy); and

Cable C-140: Possum (UK).

In general this type of circuitry implementation, with integrated driver, sensor, comparator, auto-calibration, logic circuit can perform continuous averaging of the baseline capacitance value (resting or active monitoring state), and continuously reset (re-define) the appropriate alarm generation “differential window” value parameters, either above or below established baseline parameter values.

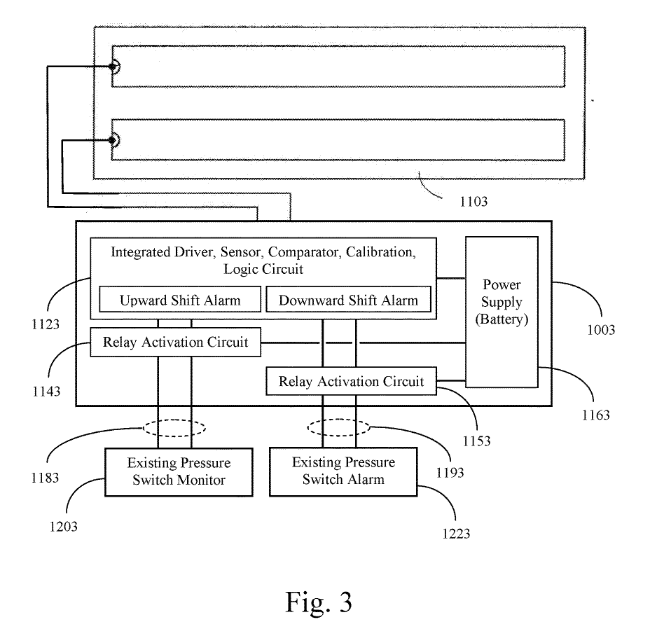

FIG. 3 is a schematic block diagram of a further alternate circuitry configuration of the system of the present invention that integrates the necessary circuitry into a dual output interconnect component. This connection circuitry embodiment permits the alarm activation of existing pressure switch monitors from either detection of an appropriate upward or downward dielectric shift from an established capacitive monitoring baseline parameter. In this view, a flexible capacitance sensor 1103 (a dielectric shift sensor) is shown connected to the integrated interconnect cable component 1003 of the present invention. Interconnect component 1003 includes four basic elements incorporated into a single module. These include integrated driver, sensor, comparator, calibration, logic circuit 1123; two relay activation circuits 1143 & 1153; and power supply (battery) 1163. Circuit 1123 takes the dielectric shift measured across the contacts for sensor mat 1103 and drives relay activation circuit 1143 if there is an upward shift alarm and relay activation circuit 1153 if there is a downward shift alarm, all according to the condition of the mat (patient on or patient off). Relay activation circuit 1143 in turn provides the on/off switch condition that the existing pressure switch monitor circuit 1203 expects to see at the connection cable 1183. Relay activation circuit 1153 in turn provides the on/off switch condition that the existing pressure switch alarm circuit 1223 expects to see at the connection cable 1193.

Although the present invention has been described in terms of the foregoing preferred embodiment, this description has been provided by way of explanation only, and is not intended to be construed as a limitation of the invention. Those skilled in the art will recognize modifications of the present invention that might accommodate specific pressure switch sensor control unit modules. Such modifications, as to cable length, connector structure, individual wire numbers and arrangements, and even sensor configurations, where such modifications are coincidental to the type of sensors and control units being utilized, do not necessarily depart from the spirit and scope of the invention.

I claim:

1. An integrated interconnect cable component for allowing the operation of dielectric shift sensor elements with a variety of control monitors associated with pressure switch based patient alarm systems, the interconnect cable component comprising:
a sensor circuit connected to the dielectric shift sensor elements;
a comparator circuit;
a calibration circuit;
a logic circuit;
a driver circuit;
a relay activation circuit; and
a power supply;
wherein the interconnect cable component takes the dielectric shift measured and drives the relay activation circuit accordingly.
